(19) United States
(12) Patent Application Publication
(10) Pub. No.: US 2017/0338180 A1
(43) Pub. Date: Nov. 23, 2017

(54) METHOD OF MAKING VERTICAL AND BOTTOM BIAS E-FUSES AND RELATED DEVICES

(71) Applicant: GLOBALFOUNDRIES Inc., Grand Cayman (KY)

(72) Inventors: Scott BEASOR, Greenwich, NY (US); Jagar SINGH, Clifton Park, NY (US)

(21) Appl. No.: 15/157,582

(22) Filed: May 18, 2016

(51) Int. Cl. H01L 23/525; H01L 27/06; H01L 23/522; H01L 21/8234; H01L 23/34; H01L 29/45; H01L 23/528

(52) U.S. Cl. CPC H01L 23/5256; H01L 29/45; H01L 27/0617; H01L 23/528; H01L 21/823418; H01L 23/34; H01L 21/823437; H01L 23/5226

(57) ABSTRACT

A method for producing semiconductor devices including an electrical fuse (e-fuse) and the resulting device are provided. Embodiments include forming a gate electrode (PC); forming at least one gate contact (CB) over the PC; forming at least one source/drain contact (CA); and forming an e-fuse including a resistor metal (RM) between at least one CB and an equal number of CAs to dissipate heat generated by the PC.

### TECHNICAL FIELD

The present disclosure relates to semiconductor devices having electrically programmable fuses (e-fuse). In particular, the present disclosure relates to e-fuse designs for semiconductor devices in advanced technology nodes.

### BACKGROUND

The e-fuse plays an important role in device programming. In computing, e-fuses are used as a means to allow for the dynamic, real-time reprogramming of computer chips. Speaking abstractly, computer logic is generally “etched” or “hard-coded” onto a silicon chip and cannot be changed after the chip has been manufactured. By utilizing an e-fuse, or a number of individual e-fuses, a chip manufacturer can change some aspects of the circuits on a chip. If a certain sub-system fails, or is taking too long to respond, or is consuming too much power, the chip can instantly change its behavior by blowing an e-fuse. Programming of an e-fuse is typically accomplished by forcing a large electrical current through the e-fuse. This high current is intended to break or rupture a portion of the e-fuse structure, which results in an “open” electrical path. In some applications, lasers are used to blow e-fuses. Fuses are frequently used in integrated circuits to program redundant elements or to replace identical defective elements. Further, e-fuses can be used to store die identification or other such information, or to adjust the speed of a circuit by adjusting the resistance of the current path. Device manufacturers are under constant pressure to produce integrated circuit products with increased performance and lower power consumption relative to previous device generations. This drive applies to the manufacture and use of e-fuses as well.

The structure of an e-fuse utilizes electro-migration to change the resistance of a device. In particular, dynamic real-time reprogramming of computer chips is possible with e-fuses. By utilizing e-fuses, the circuits on a chip can change while in operation by blowing an e-fuse to change the chip's behavior. An e-fuse is typically narrow and thin film in design to facilitate blowing. With current designs it is difficult to achieve a programming window with good yield due to the narrow window blowing of fuse. A particular problem with a middle of the line (MOL) e-fuse is achieving a good yield at a low voltage operation.

A need therefore exists for methodology enabling manufacture of improved e-fuse design that provides enhanced performance and minimizes area design requirements and the resulting device.

### SUMMARY

An aspect of the present disclosure is to provide a MOL e-fuse in the smallest area design with source/drain contact (CA) and gate contact (CB) placement to improve yield. Another aspect of the present disclosure is to utilize existing integration schemes and photolithographic layers to enable efficient layout while providing low operation voltage designs.

Another aspect of the present disclosure is to provide an e-fuse that performs as a heat sink to provide contact and heat dissipation with underneath active devices. As will be readily apparent to those skilled in the art upon a complete reading of the present application, the various embodiments of the e-fuses disclosed herein may be employed on any type of integrated circuit product, including, but not limited to, logic devices, memory devices, ASICs, so-called system-on-chip products, etc.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including forming a gate electrode (PC); forming at least one CB over the PC; forming at least one CA; and forming an e-fuse including a resistor metal (RM) between at least one CB and an equal number of CAs to dissipate heat generated by the PC.

Aspects of the present disclosure include connecting the at least one CA to a metal 1 landing or via landing, wherein the e-fuse is a middle of the line (MOL) e-fuse. Other aspects include forming the PC in an anode region and the CA in a cathode region. Further aspects include forming the e-fuse with a line width that decreases in a direction towards the cathode region. Other aspects include forming a second PC on a side of the at least one CA remote from the first PC; forming at least one second CB on the second PC; and forming a second e-fuse including a RM between the at least one second CB and the CAs to dissipate heat generated by the PC. Additional aspects include forming the CA over a trench silicide contact (TS). Yet further aspects include forming the PC in a cathode region and the CA in an anode region. Other aspects include forming the e-fuse with a line width that decreases in a direction towards the cathode region. Further aspects include forming a second PC on a side of the at least one CA remote from the first PC; forming at least one second CB on the second PC; and forming a second e-fuse including a RM between the at least one second CB and the CAs to dissipate heat generated by the PC.

Another aspect of the present disclosure is a device including a PC; at least one CB formed over the PC; at least one CA; and an e-fuse including a RM formed between at least one CB and an equal number of CAs to dissipate heat generated by the PC.

Aspects include the at least one CA being connected to a metal 1 landing or via landing and wherein the e-fuse is a middle of the line (MOL) e-fuse. Other aspects include the PC being formed in an anode region and the CA in a cathode region. Further aspects include the e-fuse being formed with a line width that decreases in a direction towards the cathode region. Additional aspects include a second PC formed on a side of the at least one CA remote from the first PC; at least one second CB formed on the second PC; and a second e-fuse including a RM formed between the at least one second CB and the CAs to dissipate heat generated by the PC. Other aspects include the CA being formed over a TS. Yet further aspects include the PC being formed in a cathode region and the CA in an anode region. Other aspects include the e-fuse being formed with a line width that decreases in a direction towards the cathode region. Additional aspects include a second PC formed on a side of the at least one CA remote from the first PC; at least one second CB formed on the second PC; and a second e-fuse including a RM formed between the at least one second CB and the CAs to dissipate heat generated by the PC.

According to the present disclosure, some technical effects may be achieved in part by a method including forming a first PC and a second PC separated from the first PC; forming at least one first CB over the first PC; forming at least one second CB over the second PC; and forming an e-fuse including a RM between at least one first CB and an equal number of second CBs to dissipate heat generated by the first PC and second PC.

Aspects include forming the first PC in a cathode region; forming the second PC in an anode region; and forming the e-fuse with a line width that decreases in width in a direction towards the cathode region. Other aspects include forming a third PC on a side of the second PC remote from the first PC; forming at least one third CB over the third PC; and forming a second e-fuse including a RM between the at least one second CB and an equal number of third CBs to dissipate heat generated by the first PC and second PC.

Another aspect of the present disclosure is a device including a first PC and a second PC separated from the first PC; at least one first CB formed over the first PC; at least one second CB formed over the second PC; and an e-fuse including a RM formed between at least one first CB and an equal number of second CBs to dissipate heat generated by the first PC and second PC.

Aspects include the first PC being formed in a cathode region; the second PC being formed in an anode region; and the e-fuse being formed with a line width that decreases in width in a direction towards the cathode region. Other aspects include a third PC formed on a side of the second PC remote from the first PC; at least one third CB formed over the third PC; and a second e-fuse including a RM formed between the at least one second CB and an equal number of third CBs to dissipate heat generated by the first PC and second PC.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIG. 1A (top view) and FIG. 1B (cross-sectional view) schematically illustrate vertical e-fuse designs, in accordance with exemplary embodiments;

FIGS. 2 and 3 (top views) schematically illustrate vertical e-fuse designs, in accordance with exemplary embodiments;

FIG. 4A (top view) and FIG. 4B (cross-sectional view) schematically illustrate bottom bias e-fuse designs, in accordance with exemplary embodiments;

FIGS. 5 and 6 (top views) schematically illustrate bottom bias e-fuse designs, in accordance with exemplary embodiments;

FIGS. 7A (top view) and 7B (cross-sectional view) schematically illustrate additional vertical e-fuse designs, in accordance with exemplary embodiments;

FIGS. 8A (top view) and 8B (cross-sectional view) schematically illustrate additional vertical e-fuse designs, in accordance with exemplary embodiments;

FIGS. 9A (top view) and 9B (cross-sectional view) schematically illustrate additional vertical e-fuse designs, in accordance with exemplary embodiments; and

FIGS. 10 through 13 (top views) schematically illustrate additional vertical e-fuse designs, in accordance with exemplary embodiments.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of e-fuse designs having insufficient performance and unsatisfactory area requirements. In accordance with embodiments of the present disclosure, an e-fuse is provided that improves performance, meets area design requirements, and provides sufficient heat dissipation from active devices.

Methodology in accordance with embodiments of the present disclosure includes forming a PC; forming at least one CB over the PC; forming at least one CA; and forming an e-fuse including a RM between at least one CB and an equal number of CAs to dissipate heat generated by the PC.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

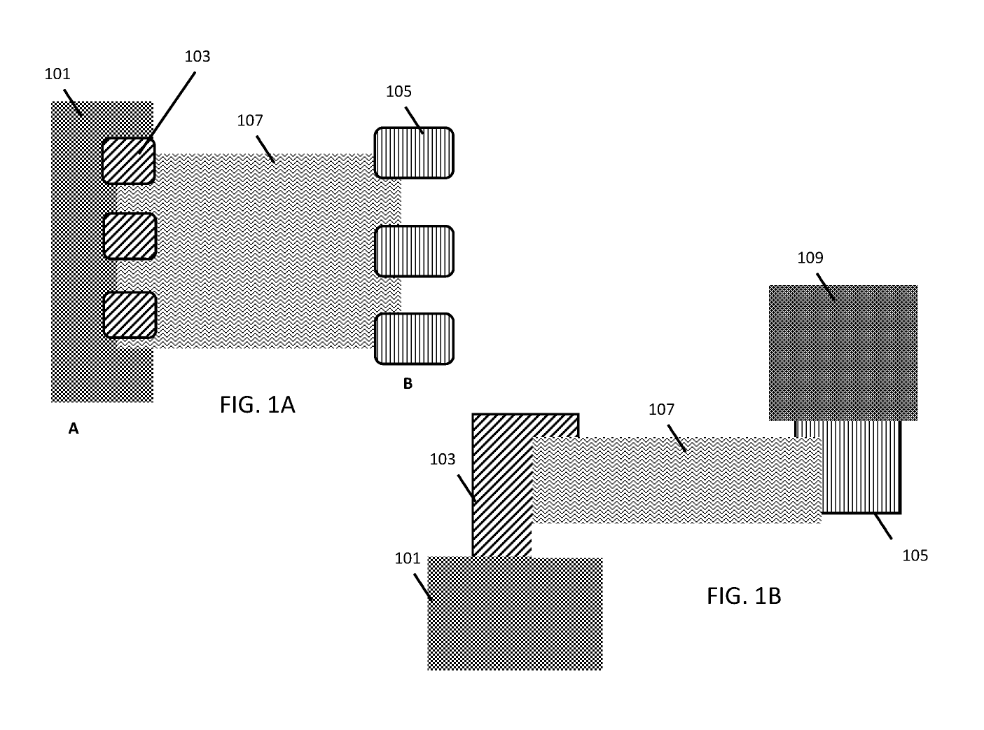

In the top view of FIG. 1A, a PC 101, such as a field effect transistor (FET), is formed over a substrate (not shown for illustrative convenience). The PC 101 can be formed by replacement metal gate (RMG) processing. FIG. 1B is a cross-sectional view of the device illustrated in FIG. 1A. Three CBs 103 are in contact with the PC 101 and formed over the PC 101. Three CAs 105 are formed over a source/drain region (not shown for illustrative convenience). In the example of FIG. 1A, the PC 101 is formed in an anode region A, and the CAs are formed in a cathode region B. An e-fuse 107 is formed over the PC 101 and in contact with the CBs 103 and CAs 105. Thus, in this example, the e-fuse 107 is considered a large vertical e-fuse since it is formed over the PC 101 and requires three CBs. The PC 101 acts as a heat sink to dissipate heat during electro-migration of the e-fuse that includes a RM. The e-fuse 107 can be formed of metals including, but not limited to, cobalt (Co), tantalum (Ta), titanium (Ti) or nickel (Ni) and silicides thereof. The heat travels through from the metal 1 landing (or via landing) 109 (FIG. 1B), then to the CAs 105, next to the e-fuse 107, then through the CBs 103, and then the heat travels to the PC 101 (FIG. 1B). Thus, the heat generated by the PC 101 is dissipated through a PC wire.

The e-fuse 107 is positioned closer to the PC 101 and supports smaller arrays and supports a low voltage operation (i.e., no voltage drop due to BEOL and VIA resistances). The vertically positioned e-fuse 107 eliminates BEOL interconnect congestion. A BEOL e-fuse in a 14 nm technology node can result in an e-fuse space reduction of 74 to 80%. A MOL e-fuse in a 14 nm technology node can result in an e-fuse space reduction of 85% to 89%.

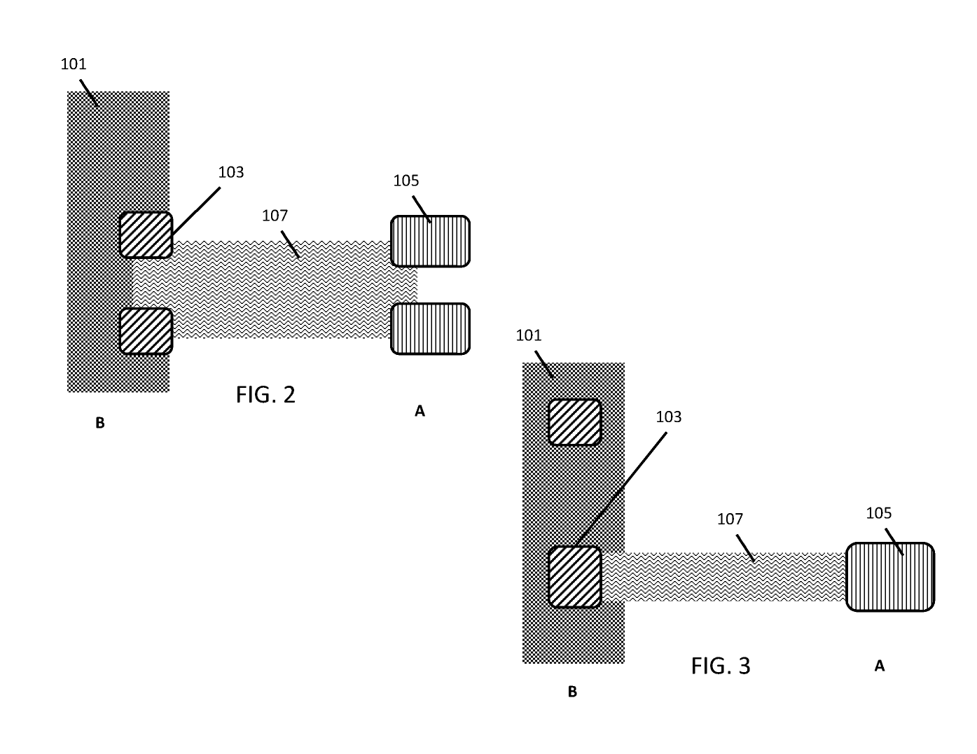

Adverting to FIG. 2, an example of a medium sized vertical e-fuse is illustrated. The PC 101 includes 2 CBs 103 and an equal number of CAs 105. The e-fuse 107 is vertically positioned over the PC 101. In FIG. 2, the CAs are formed in an anode region A and the PC is formed in cathode region B. Although not shown, a metal 1 landing 109 can be formed in contact with the CAs 105 such that a cross-sectional view would look like FIG. 1B. A BEOL medium sized e-fuse in a 14 nm technology node can result in an e-fuse space reduction of 85 to 89%. A MOL e-fuse in a 14 nm technology node can result in an e-fuse space reduction of 91% to 93%.

Adverting to FIG. 3, a third example of a vertical e-fuse is illustrated. The PC 101 includes 2 CBs 103, but only one connected to an RM, and 1 CA 105. The e-fuse 107 is vertically positioned over the PC 101. In FIG. 3, the CA is formed in an anode region A, and the PC is formed in cathode region B. Although not shown, a metal 1 landing 109 can be formed in contact with the CA 105 such that the cross-sectional view is the same as that shown in FIG. 1B. A BEOL small e-fuse in a 14 nm technology node can result in an e-fuse space reduction of 95 to 96%. A MOL e-fuse in a 14 nm technology node can result in an e-fuse space reduction of 97% to 98%.

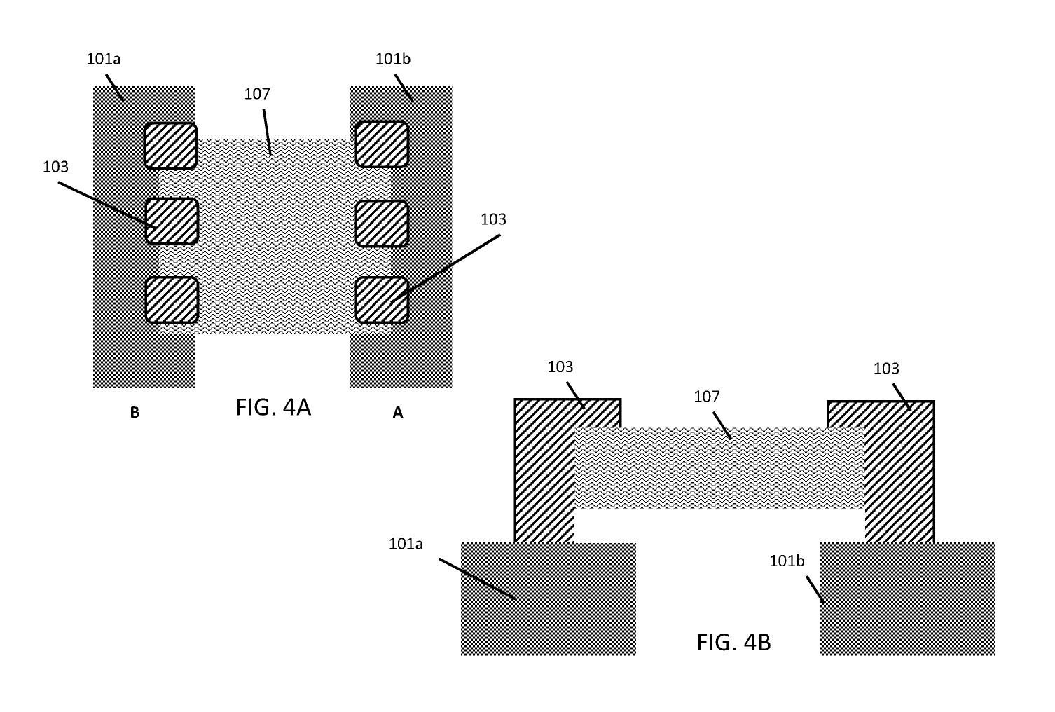

Adverting to FIG. 4A (top view), a first example of a large bottom bias MOL e-fuse is illustrated. FIG. 4B is the cross-sectional view of the device illustrated in FIG. 4A. A first PC 101a and second PC 101b each have an equal number of CBs 103. The first PC 101a is located in a cathode region B, and the second PC 101b is located in an anode region A. The e-fuse 107 is disposed in the middle of the CBs 103 and over both PC 101a and PC 101b. A BEOL e-fuse in a 14 nm technology node can result in an e-fuse space reduction of 60% to 72%. A MOL e-fuse in a 14 nm technology node can result in an e-fuse space reduction of 76% to 83.5%.

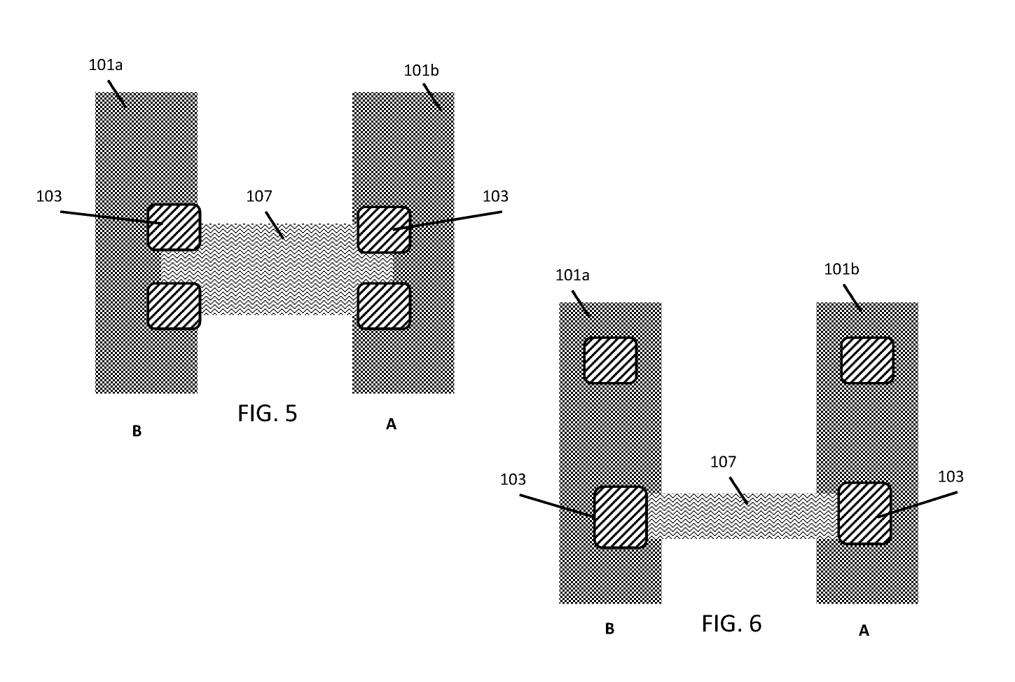

Adverting to FIG. 5, a second example of a bottom bias MOL e-fuse (a medium sized e-fuse) is illustrated. The PC 101a and PC 101b each include 2 CBs 103. The e-fuse 107 is vertically positioned over the PC 101a and PC 101b. In FIG. 5, the first PC 101a is formed in cathode region B, and the second PC 101b is formed in an anode region A. A BEOL medium sized e-fuse in a 14 nm technology node can result in an e-fuse space reduction of 77% to 84%. A MOL e-fuse in a 14 nm technology node can result in an e-fuse space reduction of 86% to 91%.

Adverting to FIG. 6, a third example of a bottom bias MOL e-fuse (a small sized e-fuse) is illustrated. The PC 101a and PC 101b each include 2 CBs 103. The e-fuse 107 is vertically positioned over the PC 101a and PC 101b, but connected to only one of the two CBs 103 over each of PCs 101a and 101b. In FIG. 6, the first PC 101a is formed in cathode region B, and the second PC 101b is formed in an anode region A. A BEOL small e-fuse in a 14 nm technology node can result in an e-fuse space reduction of 92 to 94.5%. A MOL e-fuse in a 14 nm technology node can result in an e-fuse space reduction of 95% to 97%.

The bottom bias e-fuse design eliminates BEOL metallization interconnect to the e-fuse. The area above an e-fuse can be used for BEOL routing to other devices. The e-fuse can further enable placement of an e-fuse in locations other than the die periphery.

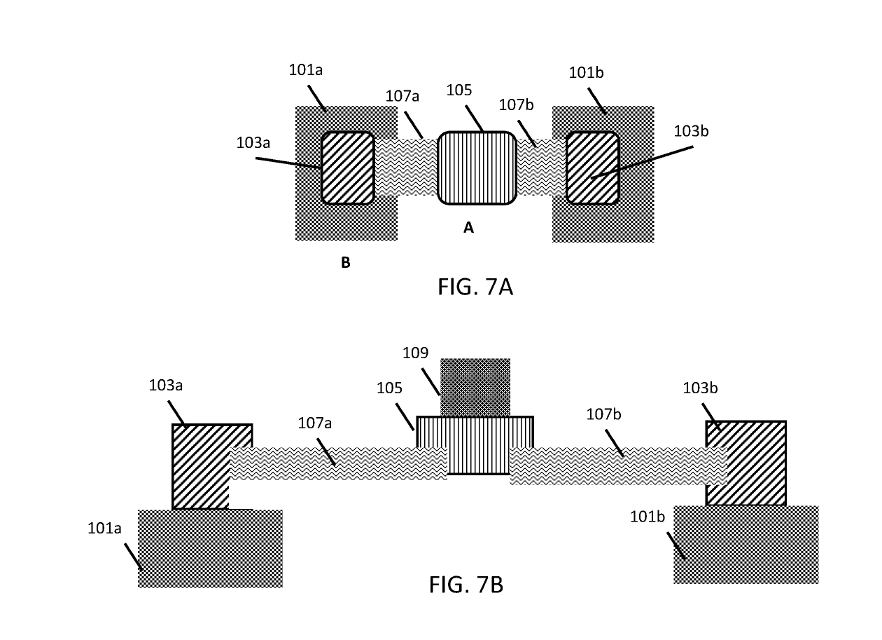

Adverting to FIGS. 7A (top view) and 7B (cross-sectional view), an example of a double vertical e-fuse design is illustrated. This example is similar to the vertical e-fuse of FIGS. 1A and 1B, providing increased e-fuse density in a given area. The first PC 101a is formed in a cathode region B, and the CA 105 is formed in an anode region A. The first e-fuse 107a is positioned over the first PC 101a and formed between the CB 103a and the CA 105. The second e-fuse 107b is positioned over the second PC 101b and formed between the CB 103b and the CA 105. In FIG. 7B, a metal 1 landing 109 is formed over the CA 105.

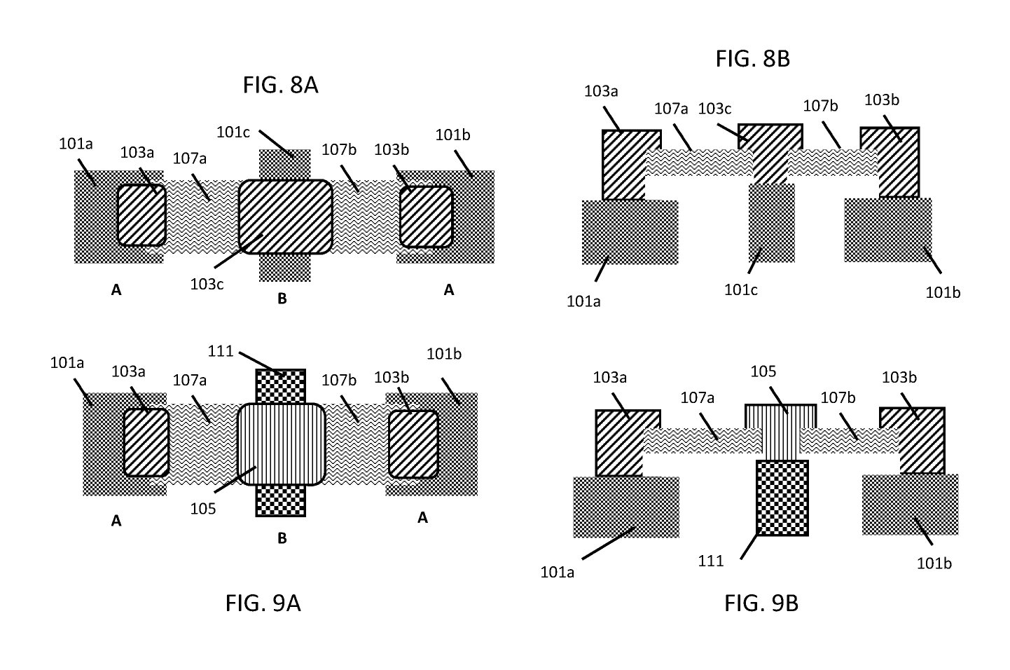

Adverting to FIGS. 8A and 8B, an example of a double bottom bias e-fuse design is illustrated in top and cross-sectional views, respectively. Three PCs 101a, 101b and 101c are shown, having a CB 103a, 103b and 103c, respectively. A first e-fuse 107a is formed between CB 103a and CB 103c and over PCs 101a and 101c. A second e-fuse 107b is formed between CB 103b and CB 103c and over PCs 101b and 101c. The first PC 101a and second PC 101b are each located in an anode region A. The third PC 101c is located in a cathode region B. The current can be tailored from the bottom side with a transistor connection.

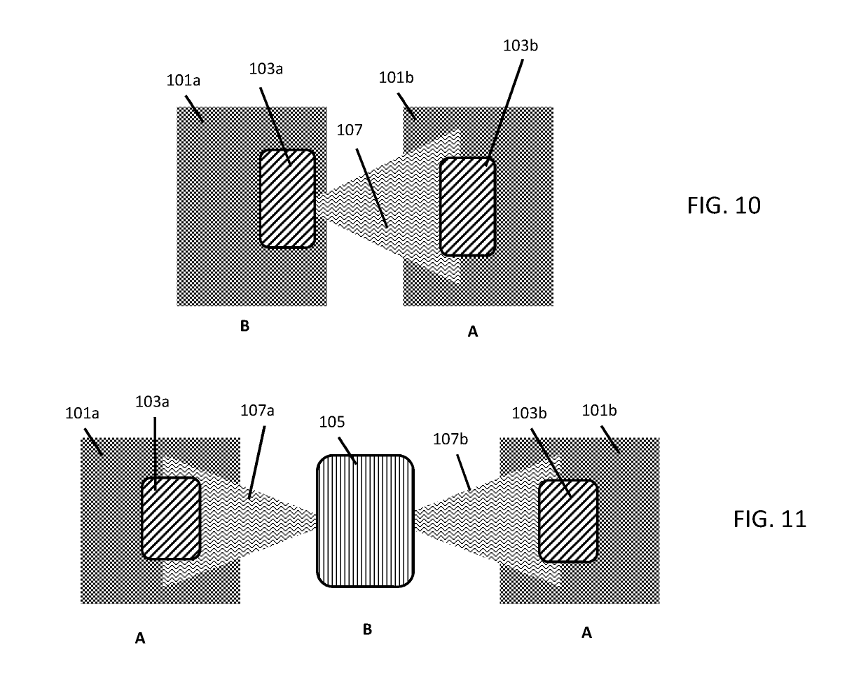

Adverting to FIGS. 9A and 9B, a second example of a double bottom bias e-fuse design is illustrated in top and cross-sectional views, respectively. Two PCs 101a and 101b are shown, with a TS 111 disposed in between. PC 101a has a single CB 103a, and PC 101b has a single CB 103b. A first e-fuse 107a is formed between CB 103a and CA 105 and positioned over PC 101a and TS 111. A second e-fuse 107b is formed between CB 103b and CA 105 and over PC 101b and TS 111. The first PC 101a and second PC 101b are each located in an anode region A. The TS 111 is located in a cathode region B. The current can be tailored from the bottom side with a transistor connection. The shared cathode in a double vertical or double bottom bias e-fuse minimizes the overall e-fuse memory area. By using a trench silicide contact or gate wires for a cathode connection, the density of the e-fuse improves.

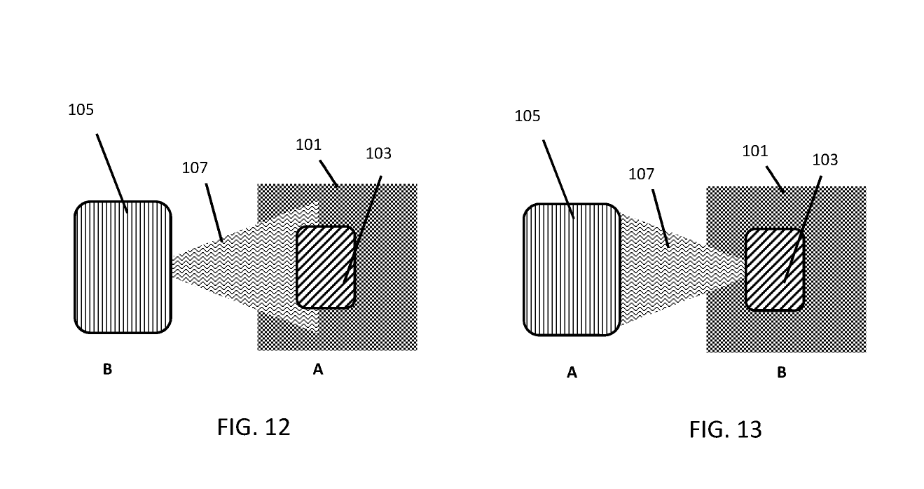

FIGS. 10 through 13 illustrate asymmetric RM e-fuse designs that can be applied to both vertical or bottom bias designs. In FIG. 10, a bottom bias e-fuse is illustrated with PC 101a and PC 101b having one CB 103a and 103b, respectively. The PC 101a is located in a cathode region B, and the PC 101b is located in an anode region A. The e-fuse 107 has a line width that decreases in a direction towards the cathode region B. The narrower line width of the e-fuse 107 towards the cathode region B allows for a low voltage operation.

In FIG. 11, a dual vertical e-fuse is illustrated with PC 101a and PC 101b having one CB 103a and 103b, respectively. The PCs 101a and 101b are located in an anode region A, and the CA 105 is located in a cathode region B. The e-fuse 107a and 107b each have a line width that decreases in a direction towards the cathode region B. The narrower line width of the e-fuses 107a and 107b towards the cathode region B allows for a low voltage operation.

Adverting to FIGS. 12 and 13, vertical e-fuse designs are illustrated. In FIG. 12, the PC 101 has a single CB 103, and the e-fuse 107 is formed over the PC 101 between CB 103 and CA 105. In FIG. 13, the PC 101 has a single CB 103, and the e-fuse 107 is formed over the PC 101 between CB 103 and CA 105. The narrower line width of the e-fuse 107 in FIGS. 12 and 13 towards the cathode region B allows for a low voltage operation.

The embodiments of the present disclosure can achieve several technical effects, including providing a heat dissipation through a PC wire. Other technical effects include enabling low-voltage e-fuse operation by eliminating voltage drop due to BEOL and via resistances. Additional technical effects include e-fuse placement closer to field effect transistors (FETs) and subsequently supporting usage in smaller arrays. The e-fuse can be used as a repair fuse to support product sort yield enhancement. Bottom bias/double bottom bias e-fuse designs can be used for die repair, to support improving product yields. Double e-fuse configuration increases the number of fuses available in a reduced area. Other technical effects include reducing BEOL interconnect congestion, enabling BEOL wiring designs over an e-fuse area. Existing integration schemes of 14 nm and 7 nm technology nodes, for example, can be leveraged. The present disclosure enjoys industrial applicability in any of various industrial applications, e.g., microprocessors, smart phones, mobile phones, cellular handsets, set-top boxes, DVD recorders and players, automotive navigation, printers and peripherals, networking and telecom equipment, gaming systems, and digital cameras. The present disclosure therefore enjoys industrial applicability in any of various types of highly integrated semiconductor devices, particularly for advanced technology nodes.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

1. A method comprising:
forming a gate electrode (PC);
forming at least one gate contact (CB) over the PC;
forming at least one second contact (CA) over and to a side of the PC; and
forming an electrically programmable fuse (e-fuse) over the PC, the e-fuse comprising a resistor metal (RM) connected between at least one CB and an equal number of CAs providing a heat dissipation path.

2. The method according to claim 1, comprising:
connecting the at least one CA to a metal 1 landing or via landing.

3. The method according to claim 1, comprising:
forming the PC in an anode region and the CA in a cathode region.

4. The method according to claim 3, comprising:
forming the e-fuse with a line width that decreases in a direction towards the cathode region.

5. The method according to claim 3, comprising:
forming a second PC on a side of the at least one CA remote from the first PC;
forming at least one second CB on the second PC; and
forming a second e-fuse comprising a resistor metal (RM) between the at least one second CB and the CAs.

6. The method according to claim 5, comprising:
forming the CA over a trench silicide contact (TS).

7. The method according to claim 1, comprising:
forming the PC in a cathode region and the CA in an anode region.

8. The method according to claim 7, comprising:
forming the e-fuse with a line width that decreases in a direction towards the cathode region.

9. The method according to claim 7, comprising:
forming a second PC on a side of the at least one CA remote from the first PC;
forming at least one second CB on the second PC; and
forming a second electrical fuse (e-fuse) comprising a resistor metal (RM) between the at least one second CB and the CAs.

10. A device comprising:
a gate electrode (PC);
at least one gate contact (CB) formed over the PC;
at least one source/drain contact (CA); and
an electrically programmable fuse (e-fuse) comprising a resistor metal (RM) formed between at least one CB and an equal number of CAs to dissipate heat generated by the PC.

11. The device according to 10, wherein:
the at least one CA is connected to a metal 1 landing or via landing, and
the e-fuse is a middle of the line (MOL) e-fuse.

12. The device according to claim 10, wherein the PC is formed in an anode region and the CA in a cathode region.

13. The device according to claim 12, wherein the e-fuse is formed with a line width that decreases in a direction towards the cathode region.

14. The device according to claim 12, comprising:
a second PC formed on a side of the at least one CA remote from the first PC;
at least one second CB formed on the second PC; and
a second e-fuse comprising a resistor metal (RM) formed between the at least one second CB and the CAs to dissipate heat generated by the PC.

15. The device according to claim 14, wherein the CA is formed over a trench silicide (TS).

16. The device according to claim 10, wherein the PC is formed in a cathode region and the CA in an anode region.

17. The device according to claim 16, wherein the e-fuse is formed with a line width that decreases in a direction towards the cathode region.

18. The device according to claim 16, comprising:
a second PC formed on a side of the at least one CA remote from the first PC;
at least one second CB formed on the second PC; and
a second e-fuse comprising a resistor metal (RM) formed between the at least one second CB and the CAs to dissipate heat generated by the PC.

19. A method comprising:
forming a first gate electrode (PC) and a second PC separated from the first PC;
forming at least one first gate contact (CB) over the first PC;
forming at least one second CB over the second PC; and
forming an electrically programmable fuse (e-fuse) over the PC, the e-fuse comprising a resistor metal (RM) connected between at least one first CB and an equal number of second CBs providing a heat dissipation path.

20. The method according to claim 19, comprising:
forming the first PC in a cathode region;
forming the second PC in an anode region; and
forming the e-fuse with a line width that decreases in width in a direction towards the cathode region.

21. The method according to claim 19, further comprising:
forming a third PC on a side of the second PC remote from the first PC;
forming at least one third CB over the third PC; and
forming a second e-fuse comprising a resistor metal (RM) between the at least one second CB and an equal number of third CBs.

22. A device comprising:
a first gate electrode (PC) and a second PC separated from the first PC;
at least one first gate contact (CB) formed over the first PC;
at least one second CB formed over the second PC; and
an electrically programmable fuse (e-fuse) comprising a resistor metal (RM) formed between at least one first CB and an equal number of second CBs to dissipate heat generated by the first PC and second PC.

23. The device according to claim 22, wherein:
the first PC is formed in a cathode region;
the second PC is formed in an anode region; and
the e-fuse is formed with a line width that decreases in width in a direction towards the cathode region.

24. The device according to claim 22, comprising:
a third PC formed on a side of the second PC remote from the first PC;
at least one third CB formed over the third PC; and
a second e-fuse comprising a resistor metal (RM) formed between the at least one second CB and an equal number of third CBs to dissipate heat generated by the first PC and second PC.
